(19) United States
(12) Patent Application Publication
(10) Pub. No.: US 2022/0336851 A1
(43) Pub. Date: Oct. 20, 2022

(54) ALL-SOLID-STATE BATTERY CONTROL SYSTEM

(71) Applicant: SUBARU CORPORATION, Tokyo (JP)

(72) Inventors: Kohei NANBU, Tokyo (JP); Norio SUZUKI, Tokyo (JP); Hiroshi ABE, Tokyo (JP); Tomoya IIOKA, Tokyo (JP)

(73) Assignee: SUBARU CORPORATION, Tokyo (JP)

(21) Appl. No.: 17/713,466

(22) Filed: Apr. 5, 2022

(30) Foreign Application Priority Data
Apr. 14, 2021 (JP) 2021-068232

(51) Int. Cl. H01M 10/0562; H01M 10/613; H01M 50/618; H01M 10/615; G01R 31/392; G01R 31/382

(52) U.S. Cl. CPC H01M 10/0562; H01M 10/613; H01M 50/618; H01M 10/615; G01R 31/392; G01R 31/382

(57) ABSTRACT

An all-solid-state battery control system includes an all-solid-state battery, a housing, a fluid, a pressurizer, and a processor. The all-solid-state battery includes a solid electrolyte. The housing has a space containing the all-solid-state battery. The fluid is configured to fill the space of the housing. The pressurizer is configured to apply pressure to the all-solid-state battery via the fluid. The processor is configured to control a magnitude of the pressure to be applied to the all-solid-state battery by the pressurizer, on the basis of a temperature of the all-solid-state battery and a state of charge of the all-solid-state battery.

### CROSS-REFERENCE TO RELATED APPLICATION

The present application claims priority from Japanese Patent Application No. 2021-068232 filed on Apr. 14, 2021, the entire contents of which are hereby incorporated by reference.

### BACKGROUND

The technology relates to an all-solid-state battery control system that controls an all-solid-state battery that includes a battery device including a solid electrolyte.

An all-solid-state battery has been proposed that stabilizes electric power output by pressurizing a battery device including a solid electrolyte by means of oil. For example, reference is made to Japanese Unexamined Patent Application Publication No. 2010-34002.

### SUMMARY

An aspect of the technology provides an all-solid-state battery control system including an all-solid-state battery, a housing, a fluid, a pressurizer, and a processor. The all-solid-state battery includes a solid electrolyte. The housing has a space containing the all-solid-state battery. The fluid is configured to fill the space of the housing. The pressurizer is configured to apply pressure to the all-solid-state battery via the fluid. The processor is configured to control a magnitude of the pressure to be applied to the all-solid-state battery by the pressurizer, on the basis of a temperature of the all-solid-state battery and a state of charge of the all-solid-state battery.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a schematic diagram illustrating an outline configuration example of an all-solid-state battery control system according to one example embodiment of the technology.

FIG. 2 is an enlarged cross-sectional view of a configuration of an all-solid-state battery illustrated in FIG. 1.

FIG. 3 is a schematic diagram illustrating an outline configuration example of a vehicle including the all-solid-state battery control system illustrated in FIG. 1.

FIG. 4 is a flowchart illustrating control of the all-solid-state battery in the all-solid-state battery control system illustrated in FIG. 1.

FIG. 5 is an explanatory diagram illustrating an example of a look-up table indicating the relationship between a temperature of the all-solid-state battery illustrated in FIG. 1 and a SOC of the all-solid-state battery.

FIG. 6 is a flowchart illustrating details of a part of steps of the flowchart illustrated in FIG. 4.

### DETAILED DESCRIPTION

It is desired to make it possible to use an all-solid-state battery over a longer term by, for example, suppressing a decrease in battery performance due to charge and discharge.

It is desirable to provide an all-solid-state battery control system that controls an all-solid-state battery to enable the all-solid-state battery to exert favorable performance over a longer term.

In the following, some example embodiments of the technology are described in detail with reference to the accompanying drawings. Note that the following description is directed to illustrative examples of the disclosure and not to be construed as limiting to the technology. In each of the drawings referred to in the following description, elements have different scales in order to illustrate the respective elements with sizes recognizable in the drawings. Therefore, factors including, without limitation, the number of each of the elements, a dimension of each of the elements, a material of each of the elements, a ratio between the elements, relative positional relationship between the elements, and any other specific numerical value are illustrative only for easier understanding and not to be construed as limiting to the technology unless otherwise stated. Further, elements in the following example embodiments which are not recited in a most-generic independent claim of the disclosure are optional and may be provided on an as-needed basis. Throughout the specification and the drawings, elements having substantially the same function and configuration are denoted with the same reference signs to avoid redundant description.

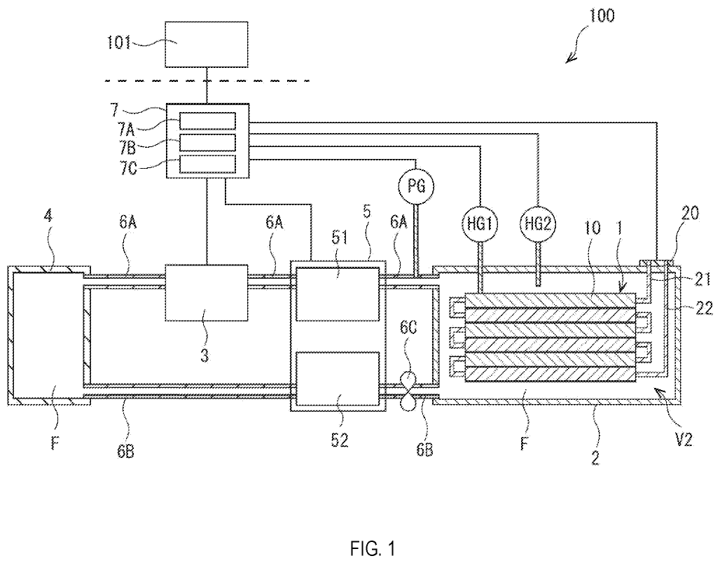

FIG. 1 schematically illustrates an outline configuration example of an all-solid-state battery control system 100 according to an example embodiment of the technology. As illustrated in FIG. 1, the all-solid-state battery control system 100 may include an all-solid-state battery 1, a housing 2, a pressurizer 3, a tank 4, a fluid temperature adjuster 5, fluid channels 6A and 6B, and a processor 7.

The all-solid-state battery 1 may be a secondary battery including a solid electrolyte as an electrolyte. A detailed configuration of the all-solid-state battery 1 will be described later.

The housing 2 may be a container having a space V2. The space V2 contains the all-solid-state battery 1. The housing 2 may include, for example, a rigid body such as stainless steel. The space V2 of the housing 2 is filled with a fluid F. The fluid F may be insulating oil, for example. The fluid F may be a fluid other than oil as long as it is able to transmit pressure. An outer surface of the housing 2 may be provided with a terminal part 20 including two output terminals 21 and 22. The output terminals 21 and 22 may each be an electric conductor through which output voltage of the all-solid-state battery 1 is extracted. For example, the output terminal 21 may be coupled to a negative electrode 11 of the all-solid-state battery 1, and the output terminal 22 may be coupled to a positive electrode 12 of the all-solid-state battery 1. The negative electrode 11 and the positive electrode 12 will be described later.

The pressurizer 3 is a unit that applies pressure to the all-solid-state battery 1 via the fluid F. The pressurizer 3 may be a pressure pump, for example. The pressurizer 3 may be communicably coupled to the processor 7, for example. The pressurizer 3 may be able to increase or reduce the pressure for the all-solid-state battery 1 via the fluid F, on the basis of a command from the processor 7.

The tank 4 may be a container that stores the fluid F.

The fluid temperature adjuster 5 may include a heater 51 that heats the fluid F and a chiller 52 that cools the fluid F. The fluid temperature adjuster 5 may be communicably coupled to the processor 7, for example. The fluid temperature adjuster 5 may be able to adjust a temperature of the fluid F, on the basis of a command from the processor 7, by heating the fluid F by means of the heater 51 or cooling the fluid F by means of the chiller 52.

The space V2 of the housing 2, and the tank 4 may be coupled to each other by the fluid channels 6A and 6B. The fluid channels 6A and 6B may both be, for example, a tubular member including a rigid body such as stainless steel. The pressurizer 3 may be disposed in the fluid channel 6A coupling the housing 2 and the tank 4. Accordingly, the fluid F may be trapped in a closed space formed by the space V2 of the housing 2, the tank 4, and the fluid channels 6A and 6B. The pressurizer 3 may cause the fluid F to circulate inside the closed space. In one example, the fluid F that reaches the pressurizer 3 may be sequentially pumped by the pressurizer 3. The fluid F may thereby pass through the fluid channel 6A to reach the space V2, and may thereafter pass through the fluid channel 6B to reach the tank 4. Thereafter, the fluid F may return to the pressurizer 3 via the fluid channel 6A. The heater 51 may be disposed in a portion, of the fluid channel 6A, between the housing 2 and the pressurizer 3. The chiller 52 may be disposed in the fluid channel 6B coupling the housing 2 and the tank 4. A fan or pump 6C configured to cause the fluid F to circulate may be further disposed in a portion, of the fluid channel 6B, between the housing 2 and the chiller 52.

The all-solid-state battery control system 100 may further include a pressure gauge PG and two temperature gauges HG1 and HG2. The pressure gauge PG may be attached to a portion, of the fluid channel 6A, coupling the heater 51 and the housing 2, for example. The pressure gauge PG may measure a pressure of the fluid F. The temperature gauge HG1 may measure a temperature of the all-solid-state battery 1, for example, a temperature of a battery device 10. The temperature gauge HG2 may measure, for example, the temperature of the fluid F present inside the space V2.

The processor 7 adjusts a magnitude of the pressure that the pressurizer 3 applies to the all-solid-state battery 1 via the fluid F, by controlling operation of the pressurizer 3. Furthermore, the processor 7 may adjust the temperature of the fluid F, by controlling operation of each of the heater 51 and the chiller 52 of the fluid temperature adjuster 5. Details of the processor 7 will be described later.

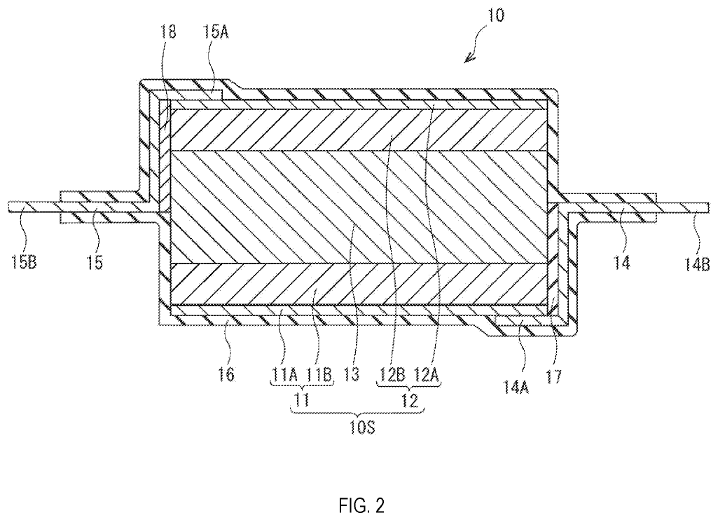

A description is given next of the detailed configuration of the all-solid-state battery 1, with reference to FIG. 2 in addition to FIG. 1. FIG. 2 is a cross-sectional view of an internal configuration of the battery device 10 of the all-solid-state battery 1.

As illustrated in FIG. 1, the all-solid-state battery 1 may include battery devices 10. The battery devices 10 may be, for example, coupled to each other in series and folded over each other in a zigzag shape.

As illustrated in FIG. 2, each of the battery devices 10 may include a stacked structure 10S including the negative electrode 11, the positive electrode 12, and a solid electrolyte layer 13 sandwiched between the negative electrode 11 and the positive electrode 12. The negative electrode 11 may include, for example, a negative electrode active material layer 11B stacked on a negative electrode current collector 11A. The positive electrode 12 may include, for example, a positive electrode active material layer 12B stacked on a positive electrode current collector 12A. The negative electrode active material layer 11B and the positive electrode active material layer 12B may each be opposed to the solid electrolyte layer 13.

The solid electrolyte layer 13 may include a solid electrolyte, for example. The solid electrolyte may have lithium ion conductivity. For example, the solid electrolyte may be a sulfide-based inorganic solid electrolyte. The sulfide-based inorganic solid electrolyte provides higher ion conductivity than other inorganic compounds. Non-limiting examples of the sulfide-based inorganic solid electrolyte may include inorganic solid electrolytes including Li₂S combined with SiS₂, GeS₂, P₂S₅, and B₂S₃.

The negative electrode current collector 11A may be a metal foil, for example. In one example, the negative electrode current collector 11A may include a copper foil. The positive electrode current collector 12A may be a metal foil, for example. In one example, the positive electrode current collector 12A may include an aluminum foil.

The negative electrode active material layer 11B may be, for example, a negative electrode mixture layer including a particulate negative electrode active material mixed with a solid electrolyte. The negative electrode active material layer 11B may further include a binder and a conductive agent. As the negative electrode active material, a carbon material, or a metal such as tin (Sn) or indium (In) may be suitably used, for example. Non-limiting examples of the negative electrode active material may include: natural graphite and various kinds of graphite; metal powder such as Sn, silicon (Si), Al, antimony (Sb), zinc (Zn), or bismuth (Bi); metal alloy powder such as Sn₅Cu₆, Sn₂Co, or Sn₂Fe; and other amorphous alloys and plating alloys.

The positive electrode active material layer 12B may be, for example, a positive electrode mixture layer including a particulate positive electrode active material mixed with a solid electrolyte. The positive electrode active material layer 12B may further include a binder and a conductive agent. As the positive electrode active material, a composite oxide of lithium and a transition metal may be suitably used, for example. Non-limiting examples of the positive electrode active material may include LiCoO₂, LiNiCoO₂, LiNiO₂, LiNiCoAlO₂, LiNiMnCoO₂, LiFeMnO₂, Li₂PtO₃, LiMnNiO₄, LiMn₂O₄, LiNiMnO₂, LiNiVO₄, LiCrMnO₄, LiFePO₄, LiFe(SO₄)₃, LiCoVO₄, and LiCOPO₄.

The battery device 10 may further include a negative electrode lead 14, a positive electrode lead 15, and a packaging material 16. The stacked structure 10S may be sealed by the packaging material 16.

The negative electrode lead 14 may have a first end 14A coupled to the negative electrode current collector 11A, and a second end 14B that is opposite to the first end 14A and extends to reach the outside of the packaging material 16. The negative electrode lead 14 may be electrically insulated, by an insulator 17, from a portion, of the stacked structure 10S, other than the negative electrode current collector 11A. The positive electrode lead 15 may have a first end 15A coupled to the positive electrode current collector 12A, and a second end 15B that is opposite to the first end 15A and extends to reach the outside of the packaging material 16. The positive electrode lead 15 may be electrically insulated, by an insulator 18, from a portion, of the stacked structure 10S, other than the positive electrode current collector 12A.

The negative electrode leads 14 and the positive electrode leads 15 may be linked to each other to couple the stacked structures 10S of the battery devices 10 in series with each other. In addition, for example, the negative electrode lead 14 of the first battery device 10 may be coupled to the output terminal 21, and the positive electrode lead 15 of the last battery device 10 may be coupled to the output terminal 22, as illustrated in FIG. 1.

The packaging material 16 may package the stacked structure 10S to seal the stacked structure 10S. The packaging material 16 may include, for example, a material with excellent flexibility and elasticity, such as rubber.

As described already, the processor 7 may be communicably coupled to the pressurizer 3, and may perform pressure control for the all-solid-state battery 1 by means of the pressurizer 3. The processor 7 may be configured by a circuit including a microcomputer, for example, as illustrated in FIG. 1. The microcomputer may include, for example, a central processing unit (CPU) 7A, a read only memory (ROM) 7B, and a random access memory (RAM) 7C. Processing based on a control method according to at least one embodiment of the technology may be implemented by the CPU executing a program stored in the ROM or the RAM. It is to be noted that the processing based on the control method according to at least one embodiment of the technology may be implemented by the CPU executing processing based on, for example, a program externally supplied by wired or wireless communication. The processor 7 may be communicably coupled to the pressure gauge PG, for example. This enables the processor 7 to obtain pressure information of the fluid F from the pressure gauge PG. The processor 7 may also be communicably coupled to the temperature gauge HG1, for example. This enables the processor 7 to obtain temperature information of the battery device 10 of the all-solid-state battery 1 from the temperature gauge HG1. The processor 7 may also be communicably coupled to the temperature gauge HG2, for example. This enables the processor 7 to obtain temperature information of the fluid F inside the space V2 from the temperature gauge HG2. Furthermore, the processor 7 may be communicably coupled to the terminal part 20. This enables the processor 7 to obtain, from the terminal part 20, information on a state of charge (SOC) of the all-solid-state battery 1 and information on an internal resistance value of the all-solid-state battery 1. The pressure control for the all-solid-state battery 1 is, for example, executed on the basis of the temperature of the all-solid-state battery 1 and the SOC of the all-solid-state battery 1. It is to be noted that the processor 7 may be communicably coupled to an external unit 101 provided outside the all-solid-state battery control system 100.

The processor 7 may, for example, control the pressurizer 3 to increase the pressure for the all-solid-state battery 1 in a continuous or stepwise manner, as the temperature of the battery device 10 of the all-solid-state battery 1 decreases. In the all-solid-state battery 1, the stacked structure 10S of the battery device 10 contracts with a decrease in the temperature thereof. This is likely to cause a gap at the interface between the negative electrode current collector 11A and the negative electrode active material layer 11B, the interface between the negative electrode active material layer 11B and the solid electrolyte layer 13, the interface between the solid electrolyte layer 13 and the positive electrode active material layer 12B, and the interface between the positive electrode active material layer 12B and the positive electrode current collector 12A. Hence, increasing the pressure for the all-solid-state battery 1 with a decrease in the temperature provides a sufficient movement path for charged elements such as lithium ions, making it possible to suppress an increase in the internal resistance value.

The processor 7 may, for example, control the pressurizer 3 to increase the pressure for the battery device 10 in a continuous or stepwise manner, as the SOC of the all-solid-state battery 1 decreases. In the all-solid-state battery 1, the stacked structure 10S of the battery device 10 contracts with a decrease in the SOC thereof. This is likely to cause a gap at the interface between the negative electrode current collector 11A and the negative electrode active material layer 11B, the interface between the negative electrode active material layer 11B and the solid electrolyte layer 13, the interface between the solid electrolyte layer 13 and the positive electrode active material layer 12B, and the interface between the positive electrode active material layer 12B and the positive electrode current collector 12A. Hence, increasing the pressure for the all-solid-state battery 1 with a decrease in the SOC provides a sufficient movement path for charged elements such as lithium ions, making it possible to suppress an increase in the internal resistance value.

In a case where heavy-load discharge of the all-solid-state battery 1 is predicted on the basis of external information, the processor 7 may control the pressurizer 3 to perform pre-pressurization of preliminarily increasing the pressure for the battery device 10. The external information may be, for example, information from the external unit 101. In a case where the all-solid-state battery control system 100 is mounted on a vehicle 200 to be described later, the external information may be, for example, information related to a change of a vehicle driving mode, map information, or travel history information of the vehicle 200, received from an electronic control unit (ECU) 213 to be described later. Furthermore, the processor 7 may learn the past travel history of the vehicle 200 by means of artificial intelligence (AI), and predict timing of the heavy-load discharge of the all-solid-state battery 1.

In a case where the all-solid-state battery 1 is predicted to switch from a charging state to a discharging state on the basis of external information, the processor 7 may control the pressurizer 3 to perform the pre-pressurization of preliminarily increasing the pressure for the battery device 10. The external information may be, for example, information from the external unit 101. In a case where the all-solid-state battery control system 100 is mounted on the vehicle 200 to be described later, the external information may be, for example, information related to the charging state duration in the travel of the vehicle 200, map information, or the travel history information of the vehicle 200, received from the ECU 213. Furthermore, the processor 7 may learn the past travel history of the vehicle 200 by means of artificial intelligence (AI), and predict timing of the switching of the all-solid-state battery 1 from the charging state to the discharging state.

The processor 7 may control the pressurizer 3 to apply additional pressure to the all-solid-state battery 1, in accordance with a degree of deterioration of the solid electrolyte included in the battery device 10. In that case, the processor 7 may determine the degree of deterioration of the solid electrolyte on the basis of accumulated operating time of the all-solid-state battery 1 or degree-of-deterioration estimation data.

Furthermore, the processor 7 may control the magnitude of the pressure to be applied to the all-solid-state battery 1 on the basis of the internal resistance value of the all-solid-state battery 1. The processor 7 may be able to obtain information on the internal resistance value of the all-solid-state battery 1 from the terminal part 20, for example.

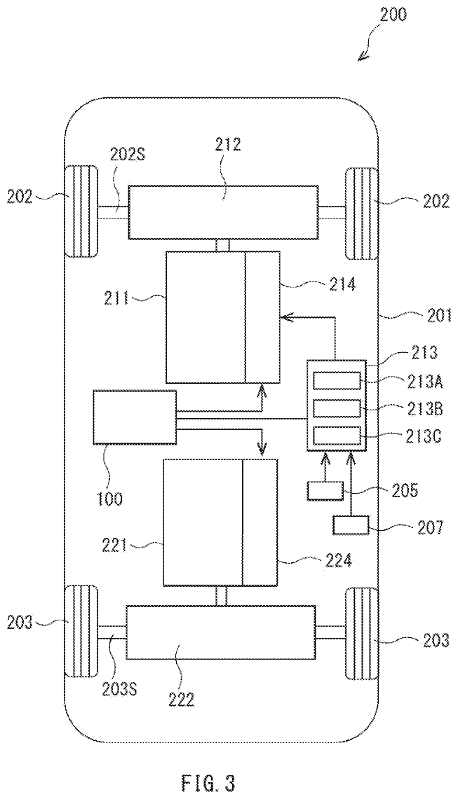

A description is given next of a configuration of the vehicle 200 mounted with the all-solid-state battery control system 100 described above. FIG. 3 schematically illustrates an outline configuration example of the vehicle 200 including the all-solid-state battery control system 100 according to the example embodiment of the technology.

As illustrated in FIG. 3, the vehicle 200 may be an electric vehicle (EV). The vehicle 200 may include a vehicle body 201, a front wheel motor 211 and a rear wheel motor 221, and a pair of front wheels 202 and a pair of rear wheels 203. The vehicle 200 may be caused to travel by the pair of front wheels 202, the pair of rear wheels 203, or both being rotated by driving force transmitted from the front wheel motor 211, the rear wheel motor 221, or both. The vehicle 200 may further include a front-wheel power transmission mechanism 212 and a rear-wheel power transmission mechanism 222, the ECU 213, and a front wheel drive circuit 214 and a rear wheel drive circuit 224. The pair of front wheels 202 may be attached to both ends of an axle 202S held by the front-wheel power transmission mechanism 212, and the pair of rear wheels 203 may be attached to both ends of an axle 203S held by the rear-wheel power transmission mechanism 222.

The front wheel motor 211 may be a three-phase alternating current motor, for example. The front wheel motor 211 may be configured to generate driving torque that rotates the front wheels 202, by means of alternating-current electric power supplied from the front wheel drive circuit 214. In causing the vehicle 200 to travel forward, the front wheel motor 211 may generate driving torque that rotates the front wheels 202 forward. In causing the vehicle 200 to travel backward, the front wheel motor 211 may generate driving torque that rotates the front wheels 202 backward.

The front-wheel power transmission mechanism 212 may be configured to transmit the driving torque transmitted from the front wheel motor 211 to the front wheels 202 via the axle 202S. The front-wheel power transmission mechanism 212 may be a gear mechanism including a torque converter, a transmission, and a differential gear, for example.

The rear wheel motor 221 may be a three-phase alternating current motor, for example. The rear wheel motor 221 may be configured to generate driving torque that rotates the rear wheels 203, by means of alternating-current electric power supplied from the rear wheel drive circuit 224. In causing the vehicle 200 to travel forward, the rear wheel motor 221 may generate driving torque that rotates the rear wheels 203 forward. In causing the vehicle 200 to travel backward, the rear wheel motor 221 may generate driving torque that rotates the rear wheels 203 backward.

The rear-wheel power transmission mechanism 222 may be configured to transmit the driving torque transmitted from the rear wheel motor 221 to the rear wheels 203 via the axle 203S. The rear-wheel power transmission mechanism 222 may be a gear mechanism including a torque converter, a transmission, and a differential gear, for example.

The front wheel drive circuit 214 and the rear wheel drive circuit 224 may, on the basis of respective control signals from the ECU 213, convert direct-current electric power supplied from the all-solid-state battery control system 100 into alternating-current electric power, and output the alternating-current electric power respectively to the front wheel motor 211 and the rear wheel motor 221.

The ECU 213 may control driving operation of the vehicle 200. In the control, the ECU 213 may comprehensively determine a travel state of the vehicle 200 on the basis of various kinds of information, such as detection signals from an operation unit 205 and a sensor group 207. The sensor group 207 may include, for example, sensors that detect an environment in which the vehicle 200 is placed and a driving state of the vehicle 200. In one example, the sensor group 207 may include an accelerator position sensor that detects an accelerator position, a speed sensor that detects a travel speed of the vehicle 200, and a gradient sensor that detects a gradient of a road surface on which the vehicle 200 travels. The sensor group 207 may send detection signals including various kinds of information from the various sensors described above to the ECU 213. The ECU 213 may be configured by a circuit including a microcomputer, for example. The microcomputer may include, for example, a central processing unit (CPU) 213A, a read only memory (ROM) 213B, and a random access memory (RAM) 213C. The ECU 213 may be communicably coupled to, for example, the processor 7 (FIG. 1) of the all-solid-state battery control system 100. The ECU 213 may send various kinds of information related to the travel of the vehicle 200 to the processor 7 (FIG. 1). For example, information related to a change of the vehicle driving mode, map information, or the travel history information of the vehicle 200 may be sent from the ECU 213 to the processor 7. The information related to the change of the vehicle driving mode may be inputted through the operation unit 205 by a driver who drives the vehicle 200.

In causing the vehicle 200 to travel forward, the driver may operate the operation unit 205 to select a drive range. If the drive range is selected by the operation unit 205, the ECU 213 may output respective appropriate torque signals to the front wheel drive circuit 214 and the rear wheel drive circuit 224 to activate the front wheel motor 211 and the rear wheel motor 221. The front wheel motor 211 and the rear wheel motor 221 may respectively generate driving torque that rotates the front wheels 202 and the rear wheels 203 in a front direction. As a result, the driving torque is transmitted to the front wheels 202 and the rear wheels 203 respectively via the front-wheel power transmission mechanism 212 and the rear-wheel power transmission mechanism 222 and the axle 202S and the axle 203S, to respectively rotate the front wheels 202 and the rear wheels 203 in the front direction. This causes the vehicle 200 to travel forward.

In causing the vehicle 200 to travel backward, the driver may operate the operation unit 205 to select a reverse range. If the reverse range is selected by the operation unit 205, the front wheel drive circuit 214 and the rear wheel drive circuit 224 may activate the front wheel motor 211 and the rear wheel motor 221, on the basis of the torque signals from the ECU 213. The front wheel motor 211 and the rear wheel motor 221 may generate driving torque that rotates the front wheels 202 and the rear wheels 203 in a direction opposite to that in the forward travel. The front wheels 202 and the rear wheels 203 may thus be rotated oppositely to the rotation in the vehicle forward travel, to cause the vehicle 200 to travel backward.

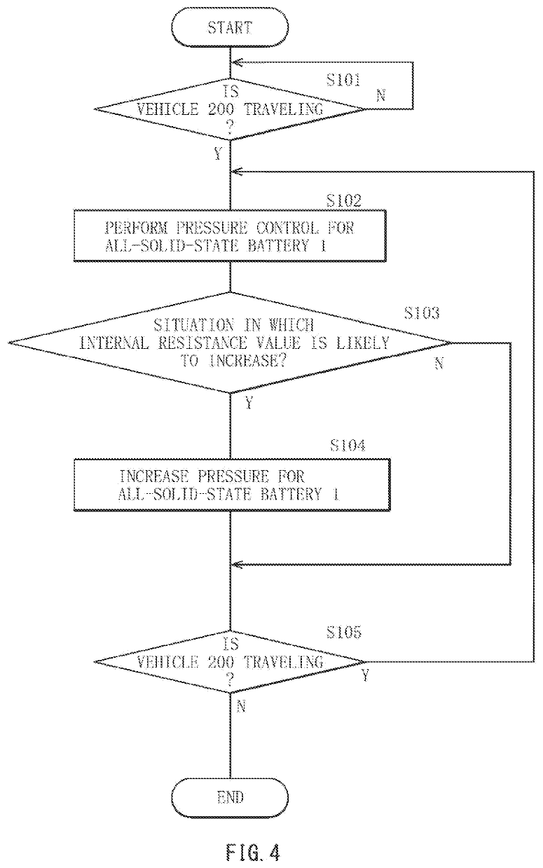

A description is given next of control of the all-solid-state battery 1 in the all-solid-state battery control system 100 illustrated in FIG. 1, with reference to FIG. 4. FIG. 4 is a flowchart illustrating the control of the all-solid-state battery 1 in the all-solid-state battery control system 100 mounted on the vehicle 200 in FIG. 3.

First, the processor 7 may determine whether the vehicle 200 is traveling, on the basis of information from the ECU 213 serving as the external unit 101 (step S101). If the vehicle 200 is determined as not traveling in step S101 (step S101: N), the processor 7 may repeat step S101 until the vehicle 200 is determined as traveling.

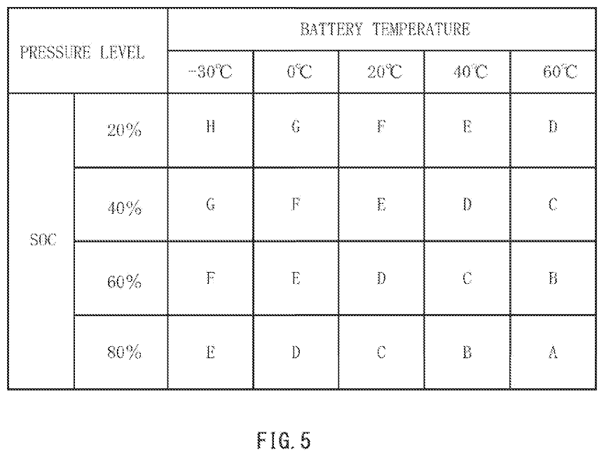

If the vehicle 200 is determined as traveling in step S101 (step S101: Y), the processor 7 may control the magnitude of the pressure that the pressurizer 3 applies to the all-solid-state battery 1 (step S102). In the control, the processor 7 may perform the pressure control for the all-solid-state battery 1, on the basis of the temperature information of the all-solid-state battery 1 from the temperature gauge HG1, and the information on the SOC of the all-solid-state battery 1. In one example, the processor 7 may control the operation of the pressurizer 3 to apply appropriate pressure to the battery device 10, on the basis of a look-up table created in advance (e.g., FIG. 5).

FIG. 5 illustrates an example of the look-up table indicating the relationship between the temperature [° C.] of the all-solid-state battery 1, i.e., a battery temperature [° C.], and the SOC [%] of the all-solid-state battery 1. FIG. 5 indicates five levels of −30, 0, 20, 40, and 60 [° C.] for the battery temperature. For each level, reference signs A to H denote respective appropriate pressure levels for the all-solid-state battery 1 corresponding to four SOC levels in a range of 20 to 80 [%]. In FIG. 5, of the pressure levels A to H, the pressure level A may be the lowest value, the subsequent pressure levels may become higher in the order of the pressure levels B, C, D, E, F, and G, and the pressure level H may be the highest value. As illustrated in FIG. 5, the processor 7 may control the pressurizer 3 to increase the pressure for the all-solid-state battery 1 in a continuous or stepwise manner, as the temperature of the all-solid-state battery 1 decreases. The processor 7 may control the pressurizer 3 to increase the pressure for the all-solid-state battery 1 in a continuous or stepwise manner, as the SOC of the all-solid-state battery 1 decreases. Furthermore, the processor 7 may finely adjust the pressure to be applied to the all-solid-state battery 1, for example, on the basis of the internal resistance value of the all-solid-state battery 1, in addition to roughly adjusting the pressure for the all-solid-state battery 1 on the basis of the temperature of the all-solid-state battery 1 and the SOC of the all-solid-state battery 1 as described above.

In performing the above-described pressure control for the all-solid-state battery 1, the processor 7 may control the temperature of the all-solid-state battery 1. In one example, to make the temperature of the battery device 10 appropriate for the battery device 10 to perform discharge, the processor 7 may adjust the temperature of the fluid F by controlling the operation of the fluid temperature adjuster 5. The temperature of the battery device 10 appropriate for the battery device 10 to perform discharge may be, for example, equal to or greater than −30° C. and equal to or less than +60° C. Thus, appropriately keeping the temperature of the battery device 10 of the all-solid-state battery 1 enables the all-solid-state battery 1 to exert sufficient battery performance.

After step S102, the processor 7 may determine whether the all-solid-state battery 1 is in a situation in which the internal resistance value of the stacked structure 10S of the battery device 10 is likely to increase (step S103). The situation in which the internal resistance value is likely to increase may be a concept including, in addition to a case where the all-solid-state battery 1 is already in a state in which the internal resistance value is likely to increase at the current point in time, a case where the all-solid-state battery 1 is expected to thereafter enter the state in which the internal resistance value is likely to increase. If the all-solid-state battery 1 is determined as not being in the situation in which the internal resistance value of the stacked structure 10S of the battery device 10 is likely to increase in step S103 (step S103: N), the flow may skip step S104 to be described later, and the processor 7 may perform the process of step S105.

If the all-solid-state battery 1 is determined as being in the situation in which the internal resistance value of the stacked structure 10S of the battery device 10 is likely to increase in step S103 (step S103: Y), the processor 7 may preliminarily further increase the pressure for the all-solid-state battery 1 (step S104). Thereafter, the processor 7 may perform the process of step S105. In step S105, the processor 7 may determine again whether the vehicle 200 is traveling, on the basis of the information from the ECU 213 serving as the external unit 101 (step S105). If the vehicle 200 is determined as traveling in step S105 (step S105: Y), the flow may return to step S102. If the vehicle 200 is determined as not traveling (step S105: N), the control of the all-solid-state battery 1 may end (END).

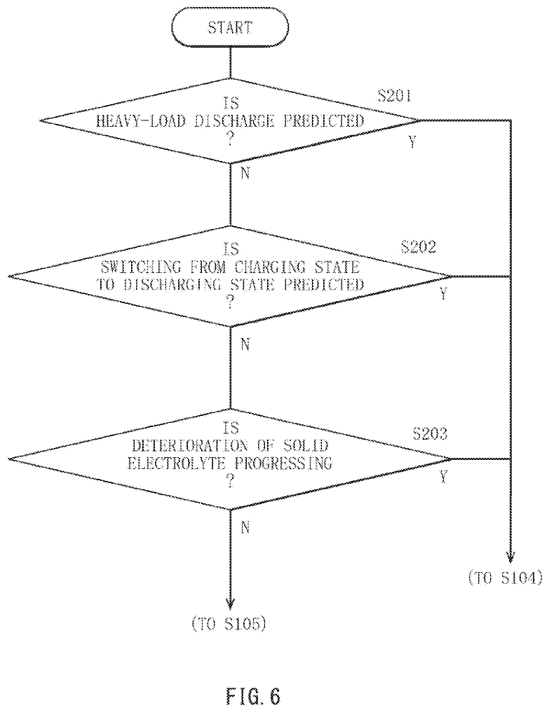

Non-limiting examples of the situation in which the internal resistance value of the stacked structure 10S is likely to increase in step S103 may include three scenes. FIG. 6 is a flowchart illustrating the control of the all-solid-state battery 1 in a further detailed process of step S103. Of the three scenes given above, the first scene may be a scene in which heavy-load discharge of the all-solid-state battery 1 is predicted. The second scene may be a scene in which the all-solid-state battery 1 is predicted to switch from the charging state to the discharging state. The third scene may be a scene in which deterioration of the solid electrolyte included in the stacked structure 10S is progressing.

As illustrated in FIG. 6, the processor 7 may determine whether heavy-load discharge of the all-solid-state battery 1 is predicted, for example, on the basis of information from the ECU 213 (step S201). A case where heavy-load discharge of the all-solid-state battery 1 is predicted may be, for example, a case where the driver makes a switch to the vehicle driving mode requesting higher output, or a case where the vehicle 200 is expected to reach a steep ascending slope within a predetermined time period. If the all-solid-state battery 1 performs such heavy-load discharge, abrupt contraction of the stacked structure 10S occurs. This can result in insufficient contact between the negative electrode 11 and the solid electrolyte layer 13 and between the positive electrode 12 and the solid electrolyte layer 13, which can cause an increase in the internal resistance value. Accordingly, if it is determined that heavy-load discharge of the all-solid-state battery 1 is predicted (step S201: Y), the processor 7 may, in step S104 (FIG. 4), control the pressurizer 3 to perform the pre-pressurization of preliminarily increasing the pressure for the all-solid-state battery 1.

If it is not determined that heavy-load discharge of the all-solid-state battery 1 is predicted (step S201: N), the flow may proceed to step S202. In step S202, the processor 7 may determine whether the all-solid-state battery 1 is predicted to switch from the charging state to the discharging state, for example, on the basis of information from the ECU 213. A case where switching from the charging state to the discharging state is predicted may be, for example, a case where input of regenerative electric power to the all-solid-state battery 1 continues for a predetermined time period by the vehicle 200 traveling on a descending slope continuously for the predetermined time period, and thereafter the vehicle 200 travels on a flat road or an ascending slope. Upon such switching from charge to discharge, abrupt contraction of the stacked structure 10S is expected to occur. This can result in insufficient contact between the negative electrode 11 and the solid electrolyte layer 13 and between the positive electrode 12 and the solid electrolyte layer 13, which can cause an increase in the internal resistance value and irreversible capacity deterioration. Accordingly, if it is determined that switching from the charging state to the discharging state is predicted (step S202: Y), the processor 7 may, in step S104 (FIG. 4), control the pressurizer 3 to perform the pre-pressurization of preliminarily increasing the pressure for the all-solid-state battery 1.

If it is not determined that switching from the charging state to the discharging state is predicted (step S202: N), the flow may proceed to step S203. In step S203, the processor 7 may, for example, determine whether deterioration of the solid electrolyte included in the stacked structure 10S is progressing. The degree of deterioration of the solid electrolyte may be determined on the basis of the accumulated operating time of the all-solid-state battery 1 or the degree-of-deterioration estimation data. In a case where deterioration of the solid electrolyte is progressing, an increase in the internal resistance value of the all-solid-state battery 1 can occur. Accordingly, if deterioration of the solid electrolyte is determined as progressing (step S203: Y), the processor 7 may, in step S104 (FIG. 4), control the pressurizer 3 to perform the pre-pressurization of preliminarily increasing the pressure for the all-solid-state battery 1. If deterioration of the solid electrolyte is not determined as progressing (step S203: N), the flow may skip step S104 to proceed to step S105 (FIG. 4). The process performed by the processor 7 in step S105 has been described above.

As described above, in the all-solid-state battery control system 100 according to the example embodiment and the vehicle 200 including the all-solid-state battery control system 100, the processor 7 executes the control of the pressure that the pressurizer 3 applies to the all-solid-state battery 1, on the basis of the temperature of the all-solid-state battery 1 and the SOC of the all-solid-state battery 1. This makes it possible to reduce a variation in output performance of the all-solid-state battery 1 that can occur depending on a situation of the temperature of the all-solid-state battery 1 and the SOC of the all-solid-state battery 1. In other words, this enables the solid electrolyte to stably keep ion conductivity. The all-solid-state battery control system 100 thus makes it possible to control the all-solid-state battery 1 to enable the all-solid-state battery 1 to exert favorable performance over a longer term.

In one example, in a case where the temperature of the all-solid-state battery 1 is low, the stacked structure 10S of the battery device 10 contracts, which is likely to cause a gap at, for example, the interface between the negative electrode 11 and the solid electrolyte layer 13 and the interface between the positive electrode 12 and the solid electrolyte layer 13. In such a case, applying pressure to the stacked structure 10S via the fluid F from the outside of the packaging material 16 reduces the gap at, for example, the interface between the negative electrode 11 and the solid electrolyte layer 13 and the interface between the positive electrode 12 and the solid electrolyte layer 13, making it possible to provide a sufficient movement path for charged elements such as lithium ions. This results in suppression of an increase in the internal resistance value, making it possible to obtain favorable output performance. In other words, it is possible to control the all-solid-state battery 1 to suppress deterioration of the battery performance and enable the all-solid-state battery 1 to exert favorable performance over a long term.

Also in a case where the SOC of the all-solid-state battery 1 is low, the stacked structure 10S of the battery device 10 contracts, which is likely to cause a gap inside the stacked structure 10S. Also in this case, as with the case where the temperature of the all-solid-state battery 1 is low, applying pressure to the stacked structure 10S via the fluid F from the outside of the packaging material 16 reduces the gap at, for example, the interface between the negative electrode 11 and the solid electrolyte layer 13 and the interface between the positive electrode 12 and the solid electrolyte layer 13, making it possible to provide a sufficient movement path for charged elements such as lithium ions. This results in suppression of an increase in the internal resistance value, making it possible to obtain favorable output performance.

In the all-solid-state battery control system 100 according to some example embodiments, the processor 7 may monitor the internal resistance value of the all-solid-state battery 1, and perform, on the basis of the internal resistance value, the pressure control for the all-solid-state battery 1 by means of the pressurizer 3. In such as manner, it is possible to perform the pressure control with higher accuracy, making it possible to obtain more stable output performance.

In the all-solid-state battery control system 100 according to some example embodiments, the heater 51 and the chiller 52 may control the temperature of the fluid F. This makes it possible to adjust the temperature of the fluid F to, for example, make the temperature of the battery device 10 appropriate for the battery device 10 to perform discharge. Accordingly, appropriately keeping the temperature of the battery device 10 of the all-solid-state battery 1 enables the all-solid-state battery 1 to exert sufficient battery performance.

In the all-solid-state battery control system 100 according to some example embodiments, the processor 7 may perform the pre-pressurization of preliminarily increasing the pressure for the battery device 10, in a case where heavy-load discharge of the all-solid-state battery 1 is predicted on the basis of the external information. In the case where the pre-pressurization is performed, it is possible to suppress a variation, e.g., an abrupt increase, in the internal resistance value as compared with a case where the pre-pressurization is not performed, enabling the all-solid-state battery 1 to exert stable battery performance.

In the all-solid-state battery control system 100 according to some example embodiments, the processor 7 may perform the pre-pressurization of preliminarily increasing the pressure for the battery device 10, in a case where the all-solid-state battery 1 is predicted to switch from the charging state to the discharging state on the basis of the external information. In the case where the pre-pressurization is performed, it is possible to suppress a variation, e.g., an abrupt increase, in the internal resistance value as compared with a case where the pre-pressurization is not performed, enabling the all-solid-state battery 1 to exert stable battery performance.

In the all-solid-state battery control system 100 according to some example embodiments, the processor 7 may control the pressurizer 3 to apply additional pressure to the all-solid-state battery 1, in accordance with the degree of deterioration of the solid electrolyte included in the battery device 10. This enables the all-solid-state battery 1 to exert higher battery performance, as compared with a case where no consideration is given to the degree of deterioration of the solid electrolyte.

Although some embodiments of the technology have been described in the foregoing by way of example with reference to the accompanying drawings, the technology is by no means limited to the embodiments described above. It should be appreciated that modifications and alterations may be made by persons skilled in the art without departing from the scope as defined by the appended claims. The technology is intended to include such modifications and alterations in so far as they fall within the scope of the appended claims or the equivalents thereof.

For example, the foregoing embodiments describe, as an example, the case where all-solid-state battery control system is mounted on a vehicle, but the technology is not limited thereto. The all-solid-state battery control system according to at least one embodiment of the technology may be mounted on, for example, a mobile object other than a vehicle, such as a vessel or an aircraft. Alternatively, the all-solid-state battery control system according to at least one embodiment of the technology may be mounted on an apparatus that does not involve movement, such as construction equipment or a work robot, to control an all-solid-state battery that is used as a power source of the apparatus. For example, the all-solid-state battery control system according to at least one embodiment of the technology may control an all-solid-state battery that is used as a household power source. Even in that case, controlling the pressure to be applied to the all-solid-state battery in accordance with a change in environmental temperature or a change in SOC makes it possible to obtain stable output performance over a long term.

In addition, in the foregoing embodiments, the processor may obtain the external information from the external unit coupled via wire, but the technology is not limited thereto. For example, the external information may be obtained from a wirelessly coupled external unit.

It is to be noted that the effects described in the present specification are merely examples and not limitative, and other effects may be achieved.

The processor 7 illustrated in FIG. 1 is implementable by circuitry including at least one semiconductor integrated circuit such as at least one processor (e.g., a central processing unit (CPU)), at least one application specific integrated circuit (ASIC), and/or at least one field programmable gate array (FPGA). At least one processor is configurable, by reading instructions from at least one machine readable non-transitory tangible medium, to perform all or a part of functions of the processor 7. Such a medium may take many forms, including, but not limited to, any type of magnetic medium such as a hard disk, any type of optical medium such as a CD and a DVD, any type of semiconductor memory (i.e., semiconductor circuit) such as a volatile memory and a non-volatile memory. The volatile memory may include a DRAM and an SRAM, and the nonvolatile memory may include a ROM and an NVRAM. The ASIC is an integrated circuit (IC) customized to perform, and the FPGA is an integrated circuit designed to be configured after manufacturing in order to perform, all or a part of the functions of the processor 7 illustrated in FIG. 1.

1. An all-solid-state battery control system comprising:
an all-solid-state battery including a solid electrolyte;
a housing having a space containing the all-solid-state battery;
a fluid configured to fill the space of the housing;
a pressurizer configured to apply pressure to the all-solid-state battery via the fluid; and
a processor configured to control a magnitude of the pressure to be applied to the all-solid-state battery by the pressurizer, on a basis of a temperature of the all-solid-state battery and a state of charge of the all-solid-state battery.

2. The all-solid-state battery control system according to claim 1, further comprising a heater configured to heat the fluid.

3. The all-solid-state battery control system according to claim 1, further comprising a chiller configured to cool the fluid.

4. The all-solid-state battery control system according to claim 2, further comprising a chiller configured to cool the fluid.

5. The all-solid-state battery control system according to claim 1, wherein
the all-solid-state battery includes a stacked structure and a packaging material, the packaging material having flexibility and sealing the stacked structure, and
the stacked structure includes a positive electrode, a negative electrode, and the solid electrolyte sandwiched between the positive electrode and the negative electrode.

6. The all-solid-state battery control system according to claim 2, wherein
the all-solid-state battery includes a stacked structure and a packaging material, the packaging material having flexibility and sealing the stacked structure, and
the stacked structure includes a positive electrode, a negative electrode, and the solid electrolyte sandwiched between the positive electrode and the negative electrode.

7. The all-solid-state battery control system according to claim 1, wherein the processor is configured to increase the pressure in a continuous or stepwise manner, as the temperature of the all-solid-state battery decreases.

8. The all-solid-state battery control system according to claim 2, wherein the processor is configured to increase the pressure in a continuous or stepwise manner, as the temperature of the all-solid-state battery decreases.

9. The all-solid-state battery control system according to claim 1, wherein the processor is configured to increase the pressure in a continuous or stepwise manner, as the state of charge of the all-solid-state battery decreases.

10. The all-solid-state battery control system according to claim 2, wherein the processor is configured to increase the pressure in a continuous or stepwise manner, as the state of charge of the all-solid-state battery decreases.

11. The all-solid-state battery control system according to claim 1, wherein the processor is configured to perform pre-pressurization of preliminarily increasing the pressure, in a case where heavy-load discharge of the all-solid-state battery is predicted on a basis of external information.

12. The all-solid-state battery control system according to claim 2, wherein the processor is configured to perform pre-pressurization of preliminarily increasing the pressure, in a case where heavy-load discharge of the all-solid-state battery is predicted on a basis of external information.

13. The all-solid-state battery control system according to claim 1, wherein the processor is configured to perform pre-pressurization of preliminarily increasing the pressure, in a case where the all-solid-state battery is predicted to switch from a charging state to a discharging state on a basis of external information.

14. The all-solid-state battery control system according to claim 2, wherein the processor is configured to perform pre-pressurization of preliminarily increasing the pressure, in a case where the all-solid-state battery is predicted to switch from a charging state to a discharging state on a basis of external information.

15. The all-solid-state battery control system according to claim 1, wherein the processor is configured to apply additional pressure to the all-solid-state battery in accordance with a degree of deterioration of the solid electrolyte.

16. The all-solid-state battery control system according to claim 2, wherein the processor is configured to apply additional pressure to the all-solid-state battery in accordance with a degree of deterioration of the solid electrolyte.

17. The all-solid-state battery control system according to claim 15, wherein the processor is configured to determine the degree of deterioration of the solid electrolyte, on a basis of accumulated operating time of the all-solid-state battery or degree-of-deterioration estimation data.

18. The all-solid-state battery control system according to claim 16, wherein the processor is configured to determine the degree of deterioration of the solid electrolyte, on a basis of accumulated operating time of the all-solid-state battery or degree-of-deterioration estimation data.

19. The all-solid-state battery control system according to claim 1, wherein the processor is configured to control the magnitude of the pressure to be applied to the all-solid-state battery, on a basis of an internal resistance value of the all-solid-state battery.

20. The all-solid-state battery control system according to claim 2, wherein the processor is configured to control the magnitude of the pressure to be applied to the all-solid-state battery, on a basis of an internal resistance value of the all-solid-state battery.
